(19) United States
(12) Patent Application Publication
(10) Pub. No.: US 2026/0025947 A1
(43) Pub. Date: Jan. 22, 2026

(54) WATER-COOLING BLOCK WITH INFORMATION DISPLAY

(71) Applicant: Cooltek Inc., Taipei City (TW)

(72) Inventor: Yin-Chen LIN, Taipei City (TW)

(21) Appl. No.: 19/219,073

(22) Filed: May 27, 2025

(30) Foreign Application Priority Data
Jul. 18, 2024 (TW) 113126862

(51) Int. Cl. H05K 7/20

(52) U.S. Cl. CPC H05K 7/20254; H05K 7/20272; F28F 2265/02

(57) ABSTRACT

A water-cooling block with information display to be used in a liquid cooling heat dissipation system. The water-cooling block comprises a heat exchange module, a casing, a liquid crystal display panel, and a light-emitting component. The casing is formed with a space for disposal of the heat exchange module. The light-emitting component includes a plurality of light-emitting sources and at least one carrier for carrying the light-emitting sources. The light-emitting sources are disposed around the space. The space is illuminated when one of the light-emitting sources is activated. The liquid crystal display panel is directly visible from the exterior of the casing and does not come with a backlight module. The liquid crystal display panel displays information based on a light in the space, the heat exchange module can be seen through the liquid crystal display panel.

### TECHNICAL FIELD

The present disclosure is drawn to a water-cooling block for a liquid cooling heat dissipation system, specifically to a water-cooling block with information display.

### BACKGROUND

A water-cooling block is a major component of a liquid cooling heat dissipation system. In the past, water-cooling blocks only focused on the efficiency of heat exchange. Now, in addition to the basic function of heat exchange, information can also be displayed on the water-cooling blocks. The relevant patents include CN204496410U, TWM601366U, TWM601368U, etc.

However, a display module added to an existing water-cooling block typically comes with its own backlight module. While this enhances the visibility of the display, the backlight module has a certain thickness, which in turn limits the overall height of the water-cooling block and cannot be effectively reduced. On the other hand, although the display module on the water-cooling block can be customized to present different visual aesthetics, the resulting visual appeal does not integrate with the water-cooling block to create a cohesive visual experience.

### BRIEF SUMMARY

A subject of the invention is to address the issue of monotonous visual aesthetics commonly associated with conventional water-cooling block.

To achieve the above-mentioned object, the invention provides a water-cooling block with information display. The water-cooling block comprises a heat exchange module, a casing provided for disposal of the heat exchange module therein, a light-emitting component arranged in the casing, and a liquid crystal display panel arranged on the casing. The casing is formed with a space for disposal of the heat exchange module therein. The light-emitting component comprises a plurality of light-emitting sources and at least one carrier for carrying the light-emitting sources. The light-emitting sources are arranged around the space. When at least one of the light-emitting sources is activated, the space is illuminated. The liquid crystal display panel is directly visible from the exterior of the casing, displays information using the light in the space, and the heat exchange module is visible through the liquid crystal display panel.

In one example, an outer surface of the heat exchange module is with a high-reflectivity color, and the high-reflectivity color further can be white or silver.

In one example, the outer surface of the heat exchange module comprises a first reflective layer arranged thereon.

In one example, the casing comprises an inner wall surface facing the space, the inner wall surface is with a high-reflectivity color, and the high-reflectivity color further can be white.

In one example, the casing comprises a second reflective layer arranged on the inner wall surface.

In one example, the casing comprises at least one mounting rib located on the inner wall surface for disposal of the at least one carrier.

In one example, the water-cooling block comprises a connection port electrically connected to the liquid crystal display panel and the light-emitting component.

In one example, the casing comprises an opening facing the liquid crystal display panel, and a transparent protective film arranged on the opening, and the transparent protective film can be replaced by an optical lens.

In one example, the heat exchange module comprises a heat exchange base and two connecting pipes, and a water flow path is formed with the heat exchange base and the two connecting pipes. Further, the heat exchange module comprises a pump disposed on the heat exchange base, and the pump forms the water flow path together with the heat exchange base and the two connecting pipes, and the water flow path is unidirectional.

In one example, the casing is formed with at least one through hole for the two connecting pipes to pass through.

Through the above-described embodiment of the present invention, the following advantages are achieved compared to conventional structures: the liquid crystal display panel of the invention displays based on the light in the casing, and does not come with a backlight module. As a result, the visual aesthetics presented by the water-cooling block are no longer limited to the information shown on the screen, allowing for a more diverse visual experience. Additionally, the absence of a backlight module allows for a reduction in both the overall height and manufacturing cost of the water-cooling block.

### BRIEF DESCRIPTION OF FIGURES

FIG. 1 is a first schematic diagram of a structural cross-section of a first example of a water-cooling block of the invention.

FIG. 2 is a schematic diagram showing a structure and appearance of the first example of the water-cooling block of the invention.

FIG. 3 is a schematic diagram of an exploded view of the first example of the water-cooling block of the invention.

FIG. 4 is a first schematic diagram of an implementation of the first example of a water-cooling block of the invention.

FIG. 5 is a second schematic diagram of the implementation of the first example of a water-cooling block of the invention.

FIG. 6 is a third schematic diagram of the implementation of the first example of a water-cooling block of the invention.

FIG. 7 is a schematic diagram of a structural cross-section of a second example of a water-cooling block of the invention.

FIG. 8 is a schematic diagram of a structural cross-section of a third example of a water-cooling block of the invention.

FIG. 9 is a schematic diagram of a structural cross-section of a fourth example of a water-cooling block of the invention.

FIG. 10 is a second schematic diagram of a structural cross-section of a first example of a water-cooling block of the invention.

### DETAILED DESCRIPTION

The detailed description and technical contents of the invention are illustrated below in connection with the drawings:

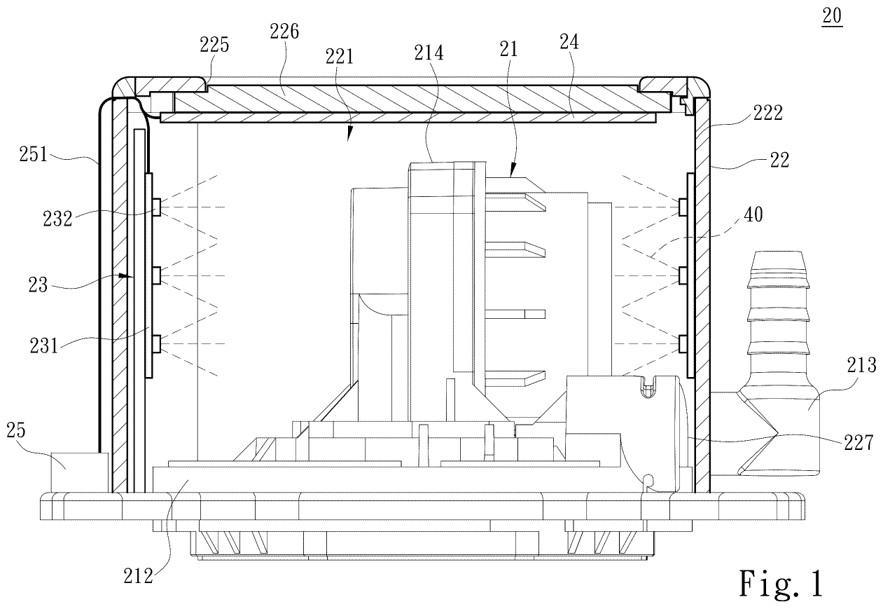

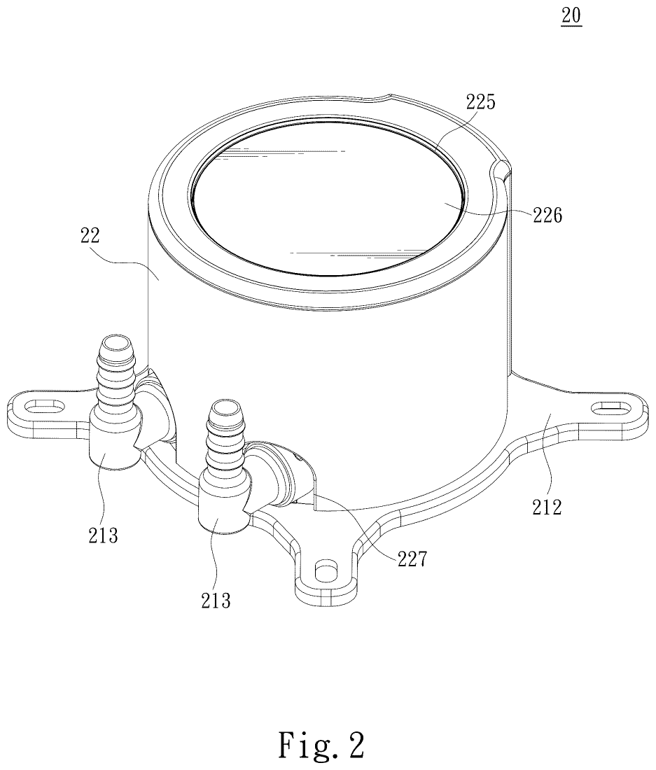

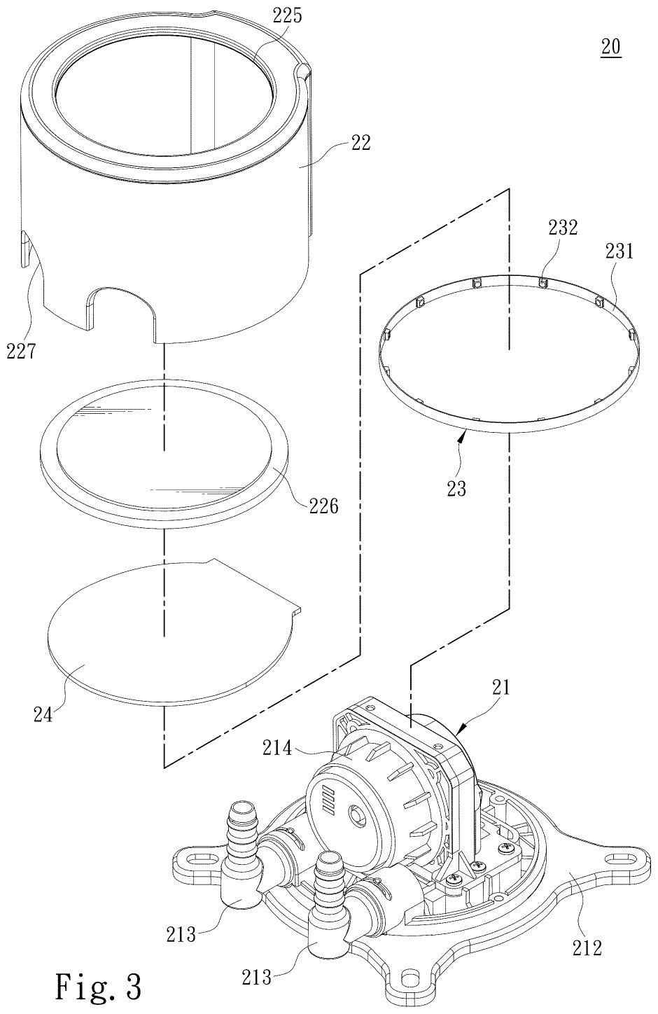

Referring to FIG. 1, FIG. 2, and FIG. 3, the invention provides a water-cooling block 20 used in a liquid cooling heat dissipation system (not shown). The water-cooling block 20 contacts a heat source (such as a CPU or a GPU) and performs heat exchange on the heat source so that the heat source can be cooled. The water-cooling block 20 of the invention includes a heat exchange module 21, a casing 22 for disposal of the heat exchange module 21 therein, a light-emitting component 23 arranged in the casing 22, a liquid crystal display panel 24 arranged on the casing 22. The casing 22 is formed with a space 221 for disposal of the heat exchange module 21 therein, and the casing covers the heat exchange module 21. When the light-emitting component 23 is activated, it illuminates the space. That is to say, when the light-emitting component 23 is activated, it projects light toward the space 221 (corresponding to reference numeral 40 in FIG. 1). The liquid crystal display panel 24 is directly visible from the exterior of the casing 22.

The liquid crystal display panel 24 of the invention includes components for display, but excludes any components that emit light or guide light (such as a backlight panel). Therefore, the light required for the liquid crystal display panel 24 of the invention to display information is obtained from components other than the liquid crystal display panel 24. On the other hand, the heat exchange module 21 can be seen through the liquid crystal display panel 24, which is transparent.

The water-cooling block 20 of the invention is connected to an external electronic device during implementation to obtain power or display signals required for operation. The display signals may be the current operating temperature, brand, trademark or animation of the heat source. The liquid crystal display panel 24 on the water-cooling block 20 is not limited to normal display.

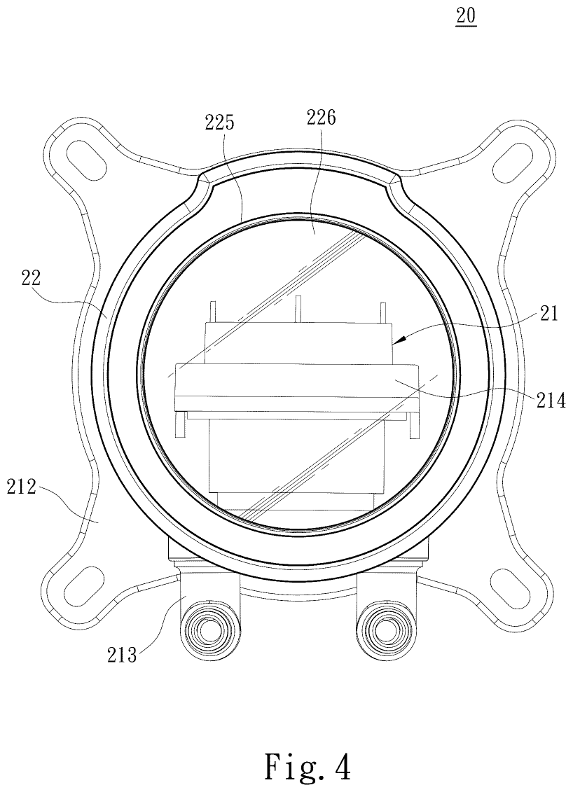

When the liquid crystal display panel 24 does not display any information and the light-emitting component 23 is activated to illuminate the space 221, the illumination within the space 221 can be observed through the liquid crystal display panel 24, and the heat exchange module 21 can also be seen at the same time, as shown in FIG. 4.

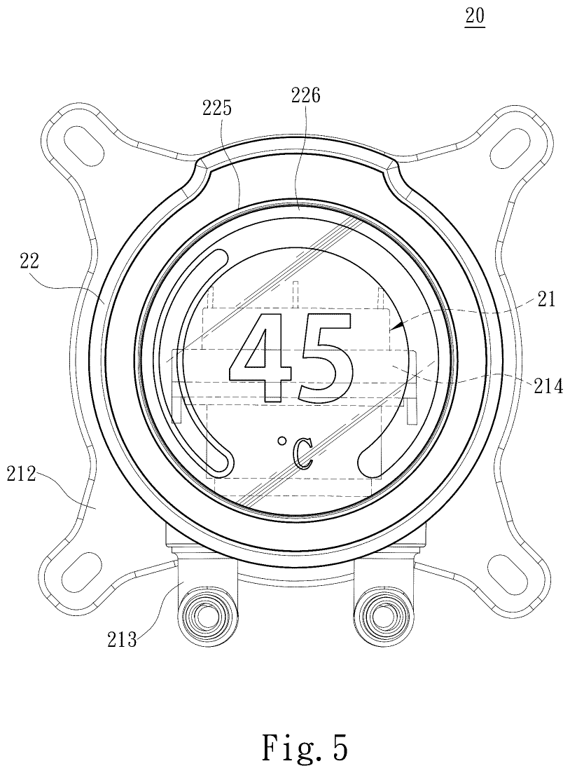

When the liquid crystal display panel 24 receives the display signals and the light-emitting component 23 is activated, the liquid crystal display panel 24 will display based on the light in the space 221, and the heat exchange module 21 can also be seen from the exterior of the casing 22 at the same time, an overlapped visual experience is as shown in FIG. 5.

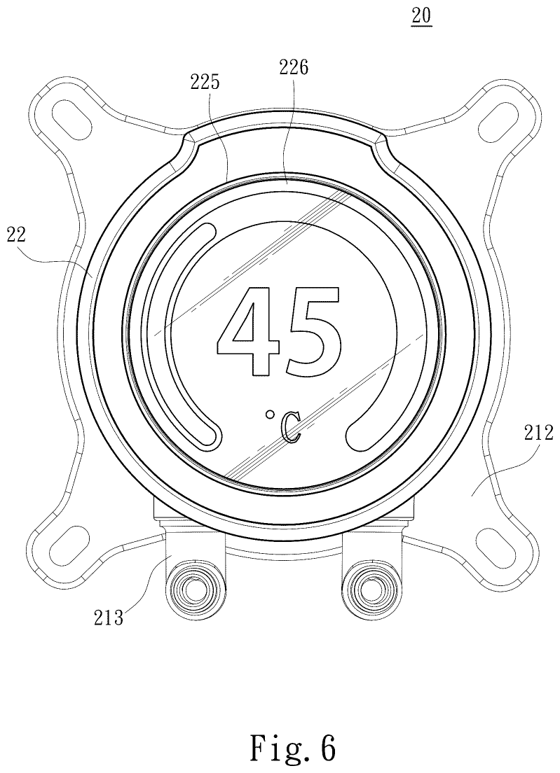

In addition to the above, the liquid crystal display panel 24 can also shield the heat exchange module 21 upon displaying, as shown in FIG. 6.

Further, the implementation of the water-cooling block 20 is not limited to the normal activation of the light-emitting component 23. When the light-emitting component 23 is not activated, the liquid crystal display panel 24 does not display anything, but the heat exchange module 21 can still be seen by approaching the water-cooling block 20.

Accordingly, the water-cooling block 20 of the invention not only displays information but also provides diverse visual experiences through the aforementioned display structure design, while also allowing the overall height of the water-cooling block 20 to be further reduced.

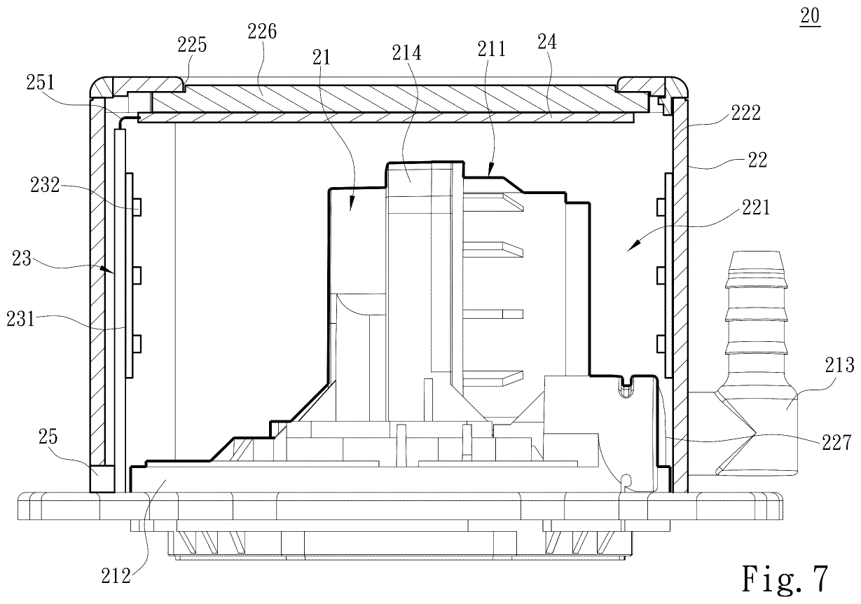

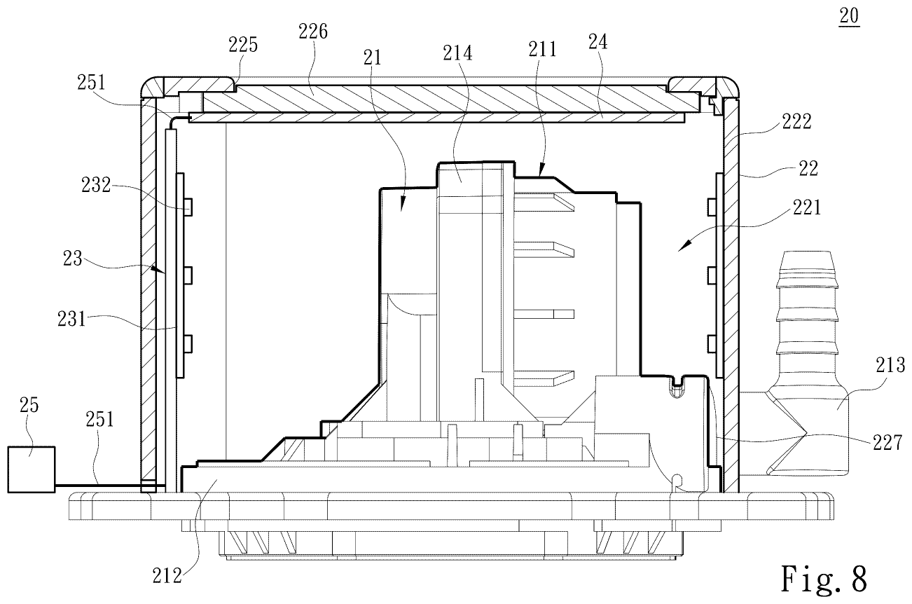

Referring to FIG. 7 and FIG. 8, to more effectively utilize the light emitted by the light-emitting component 23 for the display of the liquid crystal display panel 24, in one example, an outer surface of the heat exchange module 21 is with a high-reflectivity color, such as white or silver, to reflect the light in the space 221 leveraging the reflective properties thereof. A method of making the outer surface of the heat exchange module 21 with the high-reflectivity color includes: selecting a material with the high-reflectivity color when making a shell of the heat exchange module 21, or providing a coating on the outer surface of the heat exchange module 21 to form a first reflective layer 211.

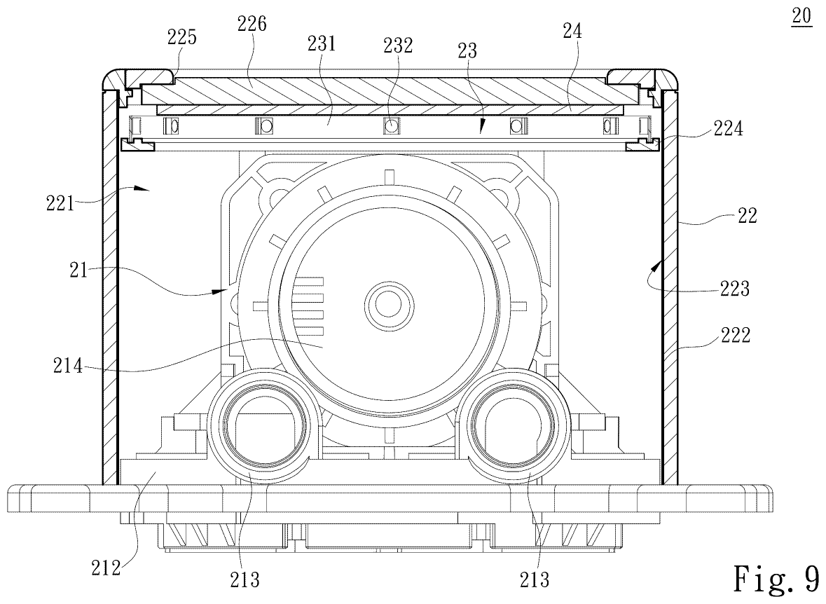

Referring to FIG. 9, in addition to the above example, in another example, the casing 22 includes an inner wall surface 222, which may also be with a high-reflectivity color. The inner wall surface 222 faces the space 221, and the inner wall surface 222 is coated with the high-reflectivity color to reflect the light emitted by the light-emitting component 23 in the space 221, thereby assisting the display of the liquid crystal display panel 24. A method of making the inner wall surface 222 of the casing 22 with the high-reflectivity color includes: selecting a material with the high-reflectivity color while manufacturing one of components used to define the space 221, when the casing 22 is composed of a plurality of components; or, selecting a material with the high-reflectivity color while manufacturing the casing 22, when the casing 22 is composed of a single component; or, providing a coating on the inner wall surface 222 of the casing 22 to form a second reflective layer 223.

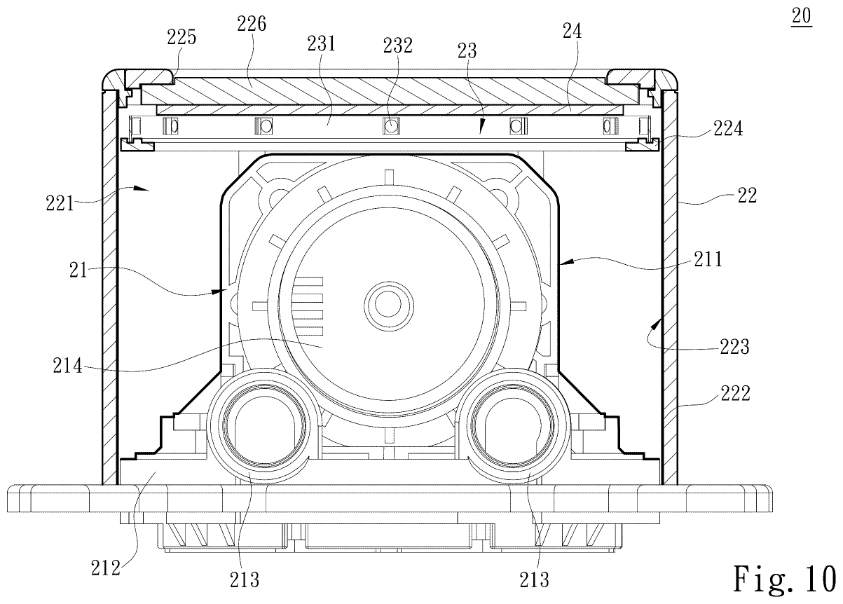

The first reflective layer 211 and the second reflective layer 223 can be of different colors, which is not limited in the invention. The first reflective layer 211 and the second reflective layer 223 can be implemented together, as shown in FIG. 10.

A position of the light-emitting component 23 in the casing 22 can be as shown in FIG. 1, or closer to the liquid crystal display panel 24 as shown in FIG. 9. In an example, the light-emitting component 23 includes a plurality of light-emitting sources 232. The light-emitting sources 232 may be single-color LED or multi-color LEDs (RGB LEDs). That is, the light-emitting sources 232 are not limited to white light.

In order to prevent local over-brightness from affecting the display of the liquid crystal display panel 24, the light-emitting sources 232 are disposed around the space 221. Furthermore, the light-emitting sources 232 can be regularly arranged on the inner wall surface 222 of the casing 22. In one example, the light-emitting component 23 further includes at least one carrier 231 carrying the light-emitting sources 232. The at least one carrier 231 may be a flexible printed circuit.

Referring back to FIG. 1, in one example, the casing 22 further includes a mounting rib 224 located on the inner wall surface 222 for disposal of the at least one carrier 231. The mounting rib 224 is not limited to a structure formed by protruding from the inner wall surface 222, but can be formed by one of the components according to the structural design of the casing 22.

Referring to FIG. 7 and FIG. 8, in one example, the water-cooling block 20 further includes at least one connection port 25 electrically connected to the liquid crystal display panel 24 and the light-emitting component 23. The at least one connection port 25 is connected to the liquid crystal display panel 24 and the light-emitting component 23 with at least one of the following or a combination thereof: at least one electrical cable 251, a flexible flat cable and a circuit board. The at least one connection port 25 transmits power and display information required for operation through at least one of the above-mentioned ones.

Further, the at least one connection port 25 may be exposed outside the casing 22 for an external connecter to connect, or the at least one electrical cable 251 (or the flexible flat cable) may be extended out of the casing 22 to be connected to other connectors.

Referring to FIG. 3, FIG. 7 and FIG. 9, in one example, the casing 22 includes an opening 225 facing the liquid crystal display panel 24, and a transparent protective film 226 arranged on the opening 225. The liquid crystal display panel 24 can be directly seen through the opening 225 from the exterior of the casing 22. Furthermore, the transparent protective film 226 is overlaid on the liquid crystal display panel 24 to provide basic protection. On the other hand, the transparent protective film 226 can be replaced by an optical lens to alter the visual experience of viewing the liquid crystal display panel 24.

Referring to FIG. 1 and FIG. 3, in an example, the heat exchange module 21 includes a heat exchange base 212 and two connecting pipes 213. A structure of the heat exchange base 212 can be easily conceived by the skilled person in the art and will not be described in detail herein. The two connecting pipes 213 are respectively connected to the two conduits of a liquid cooling heat dissipation system. The two connecting pipes 213 and the heat exchange base 212 form a water flow path. A coolant in the liquid cooling heat dissipation system will flow in the heat exchange module 21 through the water flow path.

In one example, the heat exchange module 21 further includes a pump 214 disposed on the heat exchange base 212, the pump 214 forms the water flow path together with the heat exchange base 212 and the two connecting pipes 213, and the water flow path is unidirectional. Further, the water flow path may be sequentially formed by one of the two connecting pipes 213, the pump 214, the heat exchange base 212, and the other connecting pipe 213. Alternatively, the flow path may sequentially include one of the two connecting pipes 213, the heat exchange base 212, the pump 214, and the other connecting pipe 213.

Referring to FIG. 8 and FIG. 9, in an example, the casing 22 is formed with at least one through hole 227 for the two connecting pipes 213 to pass through.

What is claimed is:

1. A water-cooling block with information display, comprising:
a heat exchange module;
a casing, formed with a space for disposal of the heat exchange module;
a light-emitting component, arranged in the casing, comprising a plurality of light-emitting sources and at least one carrier for carrying the light-emitting sources, and the light-emitting sources arranged around the space, and the space being illuminated when one of the light-emitting sources is activated; and
a liquid crystal display panel, arranged on the casing, being visible from an exterior of the casing, displaying information based on a light in the space, and the heat exchange module being visible through the liquid crystal display panel.

2. The water-cooling block with information display of claim 1, wherein an outer surface of the heat exchange module is with a high-reflectivity color.

3. The water-cooling block with information display of claim 2, wherein a high-reflectivity color is white or silver.

4. The water-cooling block with information display of claim 1, wherein an outer surface of the heat exchange module comprises a first reflective layer arranged thereon.

5. The water-cooling block with information display of claim 1, wherein the casing comprises an inner wall surface facing the space, the inner wall surface is with a high-reflectivity color.

6. The water-cooling block with information display of claim 5, wherein the casing comprises a second reflective layer arranged on the inner wall surface.

7. The water-cooling block with information display of claim 1, wherein the casing comprises an inner wall surface facing the space, and at least one mounting rib located on the inner wall surface for disposal of the at least one carrier.

8. The water-cooling block with information display of claim 1, wherein the water-cooling block comprises a connection port electrically connected to the liquid crystal display panel and the light-emitting component.

9. The water-cooling block with information display of claim 1, wherein the casing comprises an opening facing the liquid crystal display panel, and a transparent protective film arranged on the opening.

10. The water-cooling block with information display of claim 9, wherein the transparent protective film is replaced by an optical lens.

11. The water-cooling block with information display of claim 1, wherein the heat exchange module comprises a heat exchange base and two connecting pipes, and a water flow path is formed with the heat exchange base and the two connecting pipes.

12. The water-cooling block with information display of claim 11, wherein the casing is formed with at least one through hole for the two connecting pipes to pass through.

13. The water-cooling block with information display of claim 11, wherein the heat exchange module comprises a pump disposed on the heat exchange base, and the pump forms the water flow path together with the heat exchange base and the two connecting pipes, and the water flow path is unidirectional.
